(19) United States
(12) Patent Application Publication
(10) Pub. No.: US 2024/0295606 A1
(43) Pub. Date: Sep. 5, 2024

(54) METHOD AND SYSTEM FOR BATTERY PARAMETER UPDATE

(71) Applicant: ASUSTeK COMPUTER INC., Taipei City (TW)

(72) Inventors: Ke-Jen Hung, Taipei City (TW); Yu-Cheng Shen, Taipei City (TW)

(73) Assignee: ASUSTeK COMPUTER INC., Taipei City (TW)

(21) Appl. No.: 18/502,097

(22) Filed: Nov. 6, 2023

(30) Foreign Application Priority Data
Mar. 2, 2023 (TW) 112107505

(51) Int. Cl. G01R 31/367; G01R 31/3835

(52) U.S. Cl. CPC G01R 31/367; G01R 31/3835

(57) ABSTRACT

Disclosed are a method and a system for battery parameter update. The method is adapted to update a first battery parameter set of a target battery module, and includes: collecting a plurality of second battery parameter sets to a server when updating of a plurality of other battery modules are completed; classifying the second battery parameter sets based on a collection condition and storing them as reference battery parameter sets; determining whether the target battery module has not updated the first battery parameter set for more than a specified time; selecting a suitable battery parameter set close to a use state of the target battery module from the reference battery parameter sets when the target battery module does not update the first battery parameter set for more than the specified time; and updating the first battery parameter set of the target battery module according to the suitable battery parameter set.

### CROSS-REFERENCE TO RELATED APPLICATION

This application claims the priority benefit of Taiwan application serial no. 112107505, filed on Mar. 2, 2023. The entirety of the above-mentioned patent application is hereby incorporated by reference herein and made a part of this specification.

### BACKGROUND

### Technical Field

The disclosure relates to a method and system for updating battery parameters through a server.

### Description of Related Art

In today's handheld electronic products (such as notebook computers, mobile phones, and tablet computers, etc.), after lithium batteries are charged and discharged for a long period of time, the cores inside the lithium batteries will be aged gradually. Under the circumstances, if the value of battery parameters (or core parameters) for the microprocessor (MCU) (such as the battery gauge IC) inside the lithium battery to estimate the remaining stored power have not been updated with the aging of the cores, the problem of inaccurate power estimation will occur, and consequently it will be inferred that the power estimation is inaccurate.

### SUMMARY

The disclosure provides a method for updating battery parameters, which is suitable for updating the first battery parameter set of the target battery module. The method includes the following steps: collecting multiple second battery parameter sets to the server when the updating of the multiple other battery modules is completed; classifying the second battery parameter sets according to the collection conditions and storing them as reference battery parameter sets; determining whether the target battery module has not updated the first battery parameter set for more than a specified time; when the target battery module has not updated the first battery parameter set for the specified period of time, selecting a suitable battery parameter set that is close to the use state of the target battery module from the reference battery parameter sets; and updating the first battery parameter set of the target battery module according to the suitable battery parameter set.

This disclosure also provides a battery parameter updating system, which includes an electronic device and a server. The electronic device includes a target battery module with a battery core group and a processor. The target battery module is configured with a first battery parameter set. The server is configured to collect multiple second battery parameter sets when the updating of multiple other battery modules is completed, classify the second battery parameter sets according to the collection conditions, and store them as multiple reference battery parameter sets. The processor determines whether the target battery module has not updated the first battery parameter set for a specified time. When the target battery module has not updated the first battery parameter set for a specified time, the electronic device notifies the server to select a suitable battery parameter set that is close to the use state of the target battery module from the reference battery parameter sets, and update the first battery parameter set of the target battery module according to the suitable battery parameter set.

Based on the above, the battery parameter updating method and system of the present disclosure may update battery parameters for battery modules that have not yet been updated with the assistance of server and AI intelligent software, and update them dynamically at regular intervals. In this way, the updating time of battery parameters may be saved and the accuracy of power estimation may be improved, the service life of the battery module may be extended, and customer satisfaction may be improved.

To make the aforementioned more comprehensible, several embodiments accompanied with drawings are described in detail as follows.

### BRIEF DESCRIPTION OF THE DRAWINGS

FIG. 1 is a schematic block diagram of a battery parameter updating system according to an embodiment of the present disclosure.

FIG. 2 is a flowchart of a method for updating battery parameters according to an embodiment of the present disclosure.

FIG. 3 is a flowchart of a method for updating battery parameters according to another embodiment of the present disclosure.

FIG. 4 is an example of a battery parameter table according to an embodiment of the present disclosure.

### DESCRIPTION OF THE EMBODIMENTS

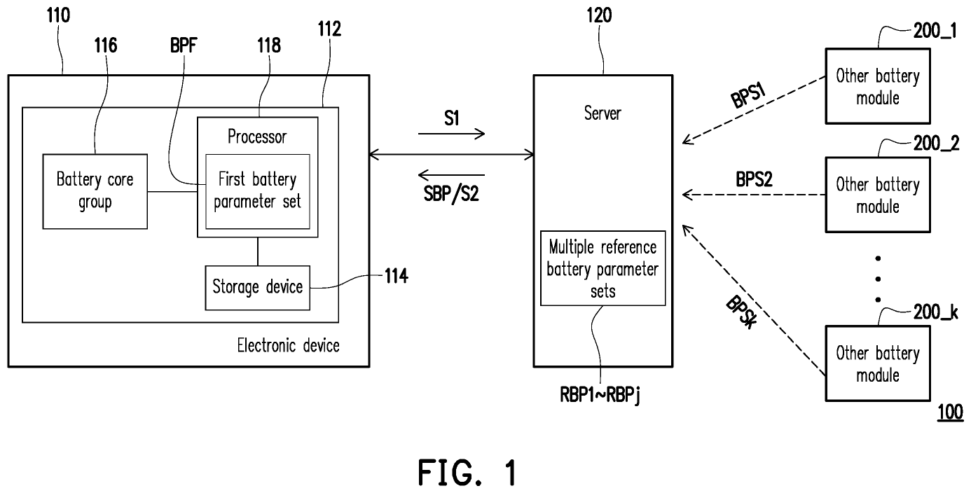

Referring to FIG. 1, the battery parameter updating system 100 includes an electronic device 110 and a server 120.

The electronic device 110 is, for example, electronic products such as a notebook computer, a mobile phone, and a tablet computer. The server 120 is, for example, a cloud database or a cloud server. In FIG. 1, the electronic device 110 includes a target battery module 112.

The target battery module 112 may be configured to supply power to the electronic device 110, and may be a built-in or an external battery module. The target battery module 112 includes a storage device 114, a battery core group (core) 116 and a processor 118. The battery core group 116 is composed of, for example, a single or multiple battery cores (battery core monomer). The processor 118 is, for example, a battery gauge IC or a microprocessor inside the battery, and may calculate the storage capacity, charging and discharging, and temperature of the target battery module 112.

The storage device 114 is, for example, any type of fixed or removable random access memory (RAM), read-only memory (ROM), flash memory, hard disks or other similar devices, hard disks or similar components, or combinations thereof. The storage device 114 is coupled to the processor 118 and may be configured to store the data required by the processor 118 for calculation. The target battery module 112 is configured with a first battery parameter set BPF. For example, n first battery parameters are included in the first battery parameter set BPF (n is any positive integer greater than 1). These first battery parameters are, for example, various battery parameter settings related to the charging voltage, charging current, discharging voltage, discharging current, temperature coefficient, internal resistance of the battery, and aging model of the target battery module 112. In this embodiment, the first battery parameters in the first battery parameter set BPF may assist the processor 118 in estimating the stored power of the target battery module 112, but the disclosure is not limited thereto. In addition, although it is shown in FIG. 1 that the storage device 114 is located in the target battery module 112, the storage device 114 may also be a device independent of the target battery module 112, such as any internal memory of the electronic device 110.

The electronic device 110 may be interconnected with the server 120 in a wireless or wired manner, through the in-built items, for example, wireless network cards that support various wireless communication protocols, such as bluetooth communication protocol, WiFi (Wireless Fidelity) communication protocol, WiFi Direct, or network cards that supports wired networks. Thereby, the processor 118 and the server 120 may communicate with each other. In addition, in some embodiments, the processor 118 itself may also be configured with network communication functions, and may directly communicate with the server 120.

The processor 118 may update the first battery parameter set BPF with the assistance of the server 120. The following embodiments illustrate the detailed steps of the battery parameter updating method of the present disclosure.

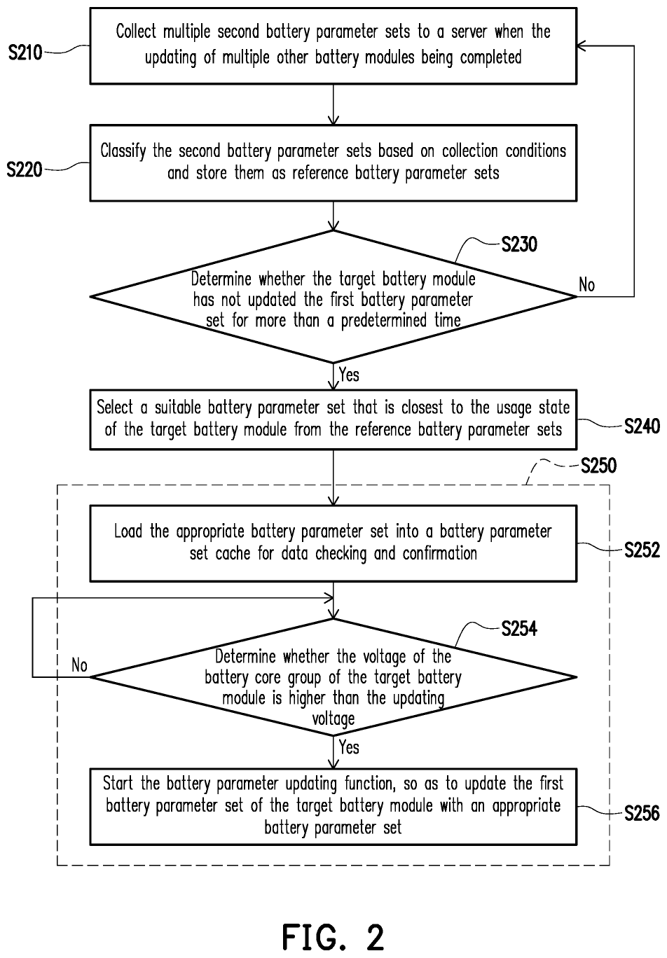

Please refer to FIG. 1 and FIG. 2 at the same time. The method of the embodiment may be applied to the battery parameter updating system 100 in FIG. 1, and the steps are described as follows.

First, in step S210, the server 120 collects multiple second battery parameter sets BPS1˜BPSk when the updating of other battery modules 200_1˜200_k is completed. In detail, the processors inside the other battery modules 200_1˜200_k may respectively detect the set second battery parameter sets BPS1˜BPSk to determine whether the battery parameter sets have been updated. When any of the other battery modules 200_1˜200_k detects that the updating of the second battery parameter set is completed, it uploads the updated second battery parameter set to the server 120. In this way, the server 120 may collect the second battery parameters when the updating is completed, so as to form multiple reference battery parameter sets RBP1˜RBPj. Similarly to the first battery parameter set BPF, the battery parameters in the second battery parameter sets BPS1˜BPSk are also related to the battery parameter settings, such as charging voltage, charging current, discharging voltage, discharging current, temperature coefficient, battery internal resistance, and the aging model of battery module etc. (k is any positive integer greater than 1.)

Next, in step S220, the server 120 classifies the second battery parameter sets BPS1˜BPSk according to the collection conditions and stores them as reference battery parameter sets RBP1˜RBPj. For example, the collection conditions include the latitude and longitude of other battery modules 200_1˜200_k, user habits (such as whether there is a habit of fully charging the battery or the frequency of use, or light and heavy loads), use situations (such as ambient temperature), and use model names, battery core materials and production dates, but the present disclosure is not limited thereto, any condition or parameter related to core aging may be configured as the collection condition of the present disclosure. In this way, the server 120 may classify the second battery parameter sets BPS1˜BPSk according to different collection conditions to generate multiple reference battery parameter sets RBP1˜RBPj, and store these reference battery parameter sets RBP1˜RBPj in the server device 120. (j is any positive integer greater than 1.)

Next, in step S230, the processor 118 determines whether the target battery module 112 has not updated the first battery parameter set BPF for more than a specified time (for example, one month). If the case is ‘no’, the process goes back to step S210 to continue to collect the second battery parameter sets BPS1˜BPSk.

If the case is ‘yes’, then in step S240, the electronic device 110 sends the notification signal S1 to the server 120 so that the AI intelligent software in the server 120 selects a suitable battery parameter set SBP that is close to the use state of the target battery module 112 from the reference battery parameter sets RBP1˜RBPj. In detail, the server 120 may obtain the use state of the target battery module 112 from the electronic device 110 (for example, one or more of the longitude and latitude of the target battery module 112, user habits, use situations, use models, battery materials, and production dates), and the AI intelligent software selects the reference battery parameter set that is close to the use state of the target battery module 112 (such as similar production dates, similar use situations, similar models, similar core materials, etc.) from multiple reference battery parameter sets RBP1˜RBPj as the suitable reference battery parameter set SBP.

In step S250, the processor 118 updates the first battery parameter set BPF of the target battery module 112 according to the suitable battery parameter set SBP. As shown in FIG. 2, step S250 includes steps S252, S254 and S256. In step S252, the processor 118 communicates with the server 120 to load the suitable battery parameter set SBP into the battery parameter set cache in the storage device 114 for data checking and confirmation. For example, the processor 118 may check and confirm the suitable battery parameter set SBP packet received by the electronic device 110 to ensure the correctness of the packet data and prevent incomplete packet data from being received.

In step S254, the processor 118 determines whether the voltage of the battery core group 116 is higher than the updating voltage (for example, 3.9 volts). When the voltage of the battery core group 116 is higher than the updating voltage, in step S256, the processor 118 starts the battery parameter updating function, so as to update the first battery parameter set BPF of the target battery module 112 with a suitable battery parameter set SBP. When the voltage of the battery core group 116 is not higher than the updating voltage, the processor keeps waiting until the voltage of the battery core group 116 is higher than the updating voltage.

By using the aforementioned method, through data classification performed by the server, it is possible to load battery parameters of other battery modules (whose production date, use situation, core materials and model are similar to the target battery module) when they are updated, directly into the electronic device where the target battery module is located. The battery parameters of the target battery module may then be updated based on the data of another user (since the production date, use situation, core materials, and model are almost the same, the degree of aging will be similar). Thereby, the updating time of the battery parameters may be saved, and the situation that the battery microprocessor may not update the battery parameters, for example, due to the inability of the gauge to meet the strict updating conditions may be overcome.

In another embodiments of the present disclosure, the storage device 114 in the electronic device 110 and the server 120 both have a previously-stored battery parameter table including multiple preset parameter sets. The server 120 may compare the suitable battery parameter set SBP with its own stored battery parameter table by AI intelligent software, and instruct the processor 118 to directly use the preset parameter set closest to the suitable battery parameter set SBP in the battery parameter table to update the first battery parameter set BPF according to the comparison result.

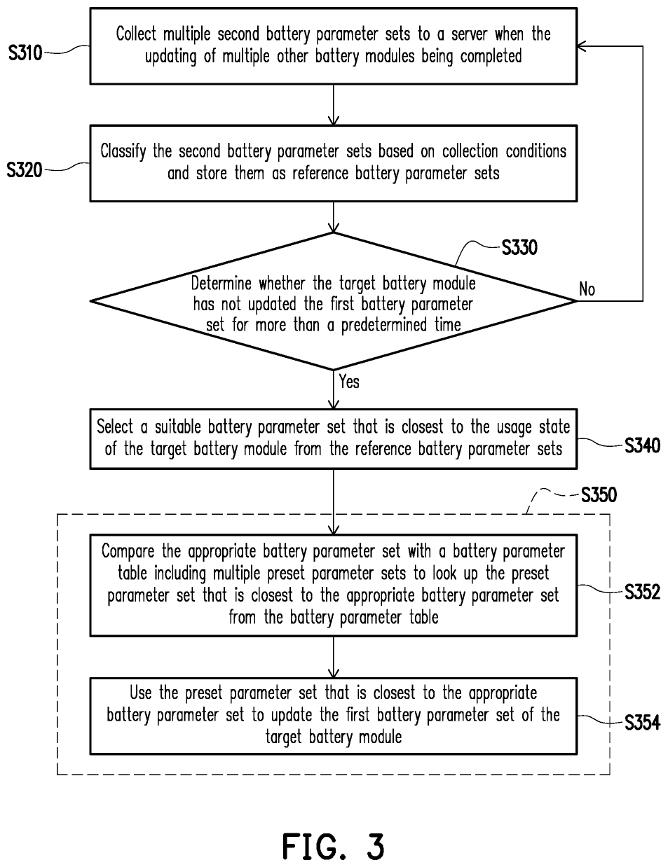

In detail, please refer to FIG. 1 and FIG. 3 at the same time. The method of this embodiment is applicable to the battery parameter updating system 100 in FIG. 1, and the steps are described as follows.

First, in step S310, the server 120 collects the second battery parameter sets BPS1˜BPSk when the other battery modules 200_1˜200_k are updated. In step S320, the server 120 classifies the second battery parameter sets BPS1˜BPSk according to the collection conditions and stores them as reference battery parameter sets RBP1˜RBPj. In step S330, the processor 118 determines whether the target battery module 112 has not updated the first battery parameter set BPF for more than a specified time (for example, one month). In step S340, the electronic device 110 notifies the server 120, by sending the notification signal S1 to the server 120, to select a suitable battery parameter set SBP that is close to the use state of the target battery module 112, from the reference battery parameter sets RBP1˜RBPj. Steps S310, S320, S330 and S340 are the same or similar to steps S210, S220, S230 and S240 in the foregoing embodiment, and the details thereof will not be repeated here.

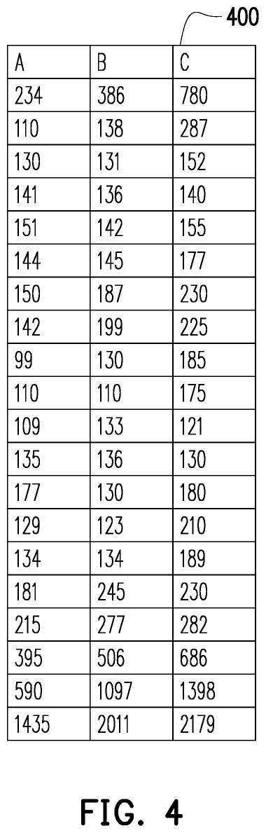

In step S350, the processor 118 updates the first battery parameter set BPF of the target battery module 112 according to the suitable battery parameter set SBP. The difference from the foregoing embodiments is that, as shown in FIG. 3, step S350 includes steps S352 and S354. In step S352, the server 120 compares the suitable battery parameter set SBP with a battery parameter table including multiple preset parameter sets to look up the preset parameter set closest to the suitable battery parameter set SBP from the battery parameter table. For example, in FIG. 4, multiple preset parameter sets related to the internal resistance of the battery are recorded in the battery parameter table 400, which are divided into three groups A, B and C. The server 120 may compare the suitable battery parameter set SBP with the preset parameters in Group A, B, and C respectively, so as to look up a set, whose values are the closet to the values of the suitable battery parameter set SBP, from Group A, B, and C, and the preset parameters in this preset parameter set are set as the parameters closest to the suitable battery parameter set SBP.

In step S354, the server 120 instructs the processor 118, by sending a notification signal S2 to the electronic device 110, to use the found parameter set (preset parameter set) closest to the suitable battery parameter set SBP to update the first battery parameter set BPF of the target battery module 112. It should be noted that since the storage device 114 in the electronic device 110 has previously stored the same battery parameter table as that of the server 120. After finding out the parameter set closest to the suitable battery parameter set SBP, the server 120 does not need to send a complete packet of the preset parameters to the electronic device 110, and it only needs to instruct the processor 118 to select which preset parameter set in the battery parameter table to be the closest suitable battery parameter set SBP. Thereby, the time required for transmitting the packet data may be omitted.

To sum up, the battery parameter updating method and system of the present disclosure may look up the most suitable battery parameters with the assistance of server, so as to continually update the battery parameters of the battery module dynamically at intervals. In this way, the updating time of battery parameters may be saved, the accuracy of power estimation may be improved, and the service life of the battery module may be extended, thereby improving customer satisfaction.

What is claimed is:

1. A battery parameter updating method, adapted to update a first battery parameter set of a target battery module, and the battery parameter updating method comprising:
collecting a plurality of second battery parameter sets to a server when updating of a plurality of other battery modules being completed;
classifying the second battery parameter sets according to at least one collection condition and storing them as a plurality of reference battery parameter sets;
determining whether the target battery module has not updated the first battery parameter set for more than a specified time;
in case that the target battery module has not updated the first battery parameter set for more than the specified time, selecting a suitable battery parameter set that is close to a use state of the target battery module from the reference battery parameter sets; and
updating the first battery parameter set of the target battery module according to the suitable battery parameter set.

2. The battery parameter updating method of claim 1, wherein the at least one collection condition comprises one or more of latitude and longitude where the other battery modules are located, user habits, use situations, use models, battery core materials, and production dates.

3. The battery parameter updating method of claim 1, wherein the updating of the first battery parameter set of the target battery module according to the suitable battery parameter set comprises:
loading the suitable battery parameter set into a battery parameter set cache for data checking and confirmation.

4. The battery parameter updating method of claim 3, wherein the updating of the first battery parameter set of the target battery module according to the suitable battery parameter set further comprises:
determining whether a voltage of a battery core group inside the target battery module is higher than an updating voltage; and
in the case that the voltage of the battery core group is higher than the updating voltage, a function of updating battery parameters is started, so as to use the suitable battery parameter set to update the first battery parameter set of the target battery module.

5. The battery parameter updating method of claim 1, wherein the updating of the first battery parameter set of the target battery module according to the suitable battery parameter set comprises:
comparing the suitable battery parameter set with a battery parameter table comprising a plurality of preset parameter sets to look up the preset parameter set that is closest to the suitable battery parameter set from the battery parameter table; and
updating the first battery parameter set of the target battery module by using the preset parameter set that is closest to the suitable battery parameter set.

6. A battery parameter updating system, comprising:
an electronic device comprising a target battery module having a battery core group and a processor, and the target battery module configured with a first battery parameter set; and
a server configured to collect a plurality of second battery parameter sets from a plurality of other battery modules when the updating of the other battery modules being completed, and classify the second battery parameter sets according to at least one collection condition, and store them as a plurality of reference battery parameter sets;
a processor judging whether the target battery module has not updated the first battery parameter set for more than a specified time, and in the case that the target battery module has not updated the first battery parameter set for the specified time, the electronic device notifying the server to select a suitable battery parameter set that is close to a use state of the target battery module from the reference battery parameter sets, and to update the first battery parameter set of the target battery module according to the suitable battery parameter set.

7. The battery parameter updating system of claim 6, wherein the at least one collection condition comprises one or more of latitude and longitude where the other battery modules are located, user habits, use situations, use models, battery core materials, and production dates.

8. The battery parameter updating system of claim 6, wherein the target battery module comprises a storage device coupled to the processor, and the processor communicates with the server, and loads the suitable battery parameter set into a battery parameter set cache in the storage device for data checking and confirmation.

9. The battery parameter updating system of claim 8, wherein the processor determines whether a voltage of the battery core group is higher than an updating voltage, and in the case that the voltage of the battery core group is higher than the updating voltage, the processor starts an updating function to use the suitable battery parameter set to update the first battery parameter set of the target battery module.

10. The battery parameter updating system of claim 6, wherein the electronic device further comprises a storage device coupled to the target battery module, and the storage device and the server store a battery parameter table comprising a plurality of preset parameter sets, and the server compares the suitable battery parameter set with the battery parameter table to look up the preset parameter set that is closest to the suitable battery parameter set from the battery parameter table, and the server instructs the processor to update the first battery parameter set of the target battery module with the preset parameter set that is closest to the suitable battery parameter set.
